(19) United States
(12) Patent Application Publication
(10) Pub. No.: US 2023/0017904 A1
(43) Pub. Date: Jan. 19, 2023

(54) PROTECTIVE CASE FOR MOBILE DEVICE AND HEAT DISSIPATION FILM THEREOF

(71) Applicants: SEIDMAN INT'L TRADING LTD., Taipei City (TW); EAPUS TECHNOLOGY INC., New Taipei City (TW)

(72) Inventors: Kuo-Wei LAI, TAIPEI CITY (TW); Shen-Hsiang LIN, NEW TAIPEI CITY (TW)

(21) Appl. No.: 17/374,321

(22) Filed: Jul. 13, 2021

(51) Int. Cl. H04B 1/3888; H05K 7/20

(52) U.S. Cl. CPC H04B 1/3888; H05K 7/2039

(57) ABSTRACT

A protective case includes a protective shell and a heat dissipation film. The protective shell has an inner wall. The heat dissipation film is attached on the inner wall. The heat dissipation film includes a plastic base layer, a heat diffusion layer and a heat absorption layer stacked sequentially in a direction away from the inner wall. Therefore, the heat dissipation film is attached on the inner wall of the protective shell to make the protective case for a mobile device possess desirable efficiency of heat dissipation.

### BACKGROUND

### Technical Field

The disclosure relates to a film structure for heat dissipation, particularly to a protective case for a mobile device and a heat dissipation film thereof.

### Related Art

Mobile devices such as tablets and mobile phones are necessary portable devices for people. Users usually cover their mobile devices with a protective case to enhance protective ability so as to reduce wear and damage when being impacted or collided.

However, there are various protective cases in the market, but most of them do not have the function of heat conduction. As a result, the heat from an operating mobile device cannot be conducted to the protective case to possibly cause crash or damage due to superheat.

In view of the above drawbacks, the inventor proposes this disclosure based on his expert knowledge and elaborate researches in order to solve the problems of related art.

### SUMMARY

An object of the disclosure is to provide a protective case for a mobile device and a heat dissipation film thereof, which the heat dissipation film is attached on an inner wall of the protective case to make the protective case for the mobile device possess desirable efficiency of heat dissipation.

To accomplish the above object, the heat dissipation film of the disclosure includes: a plastic base layer composed of polyethylene terephthalate (PET); a heat diffusion layer composed of a graphite sheet, a copper sheet, an aluminum sheet, a silver sheet or a graphene sheet; and a heat absorption layer composed of a mix of a paraffin, a rubber and an endothermic powder, and the heat diffusion layer being sandwiched between the plastic base layer and the heat absorption layer.

To accomplish the above object, the protective case for a mobile device of the disclosure includes: a protective shell having an inner wall; and a heat dissipation film, attached on the inner wall, including a plastic base layer, a heat diffusion layer and a heat absorption layer stacked sequentially in a direction away from the inner wall.

Accordingly, the heat dissipation film is attached on the inner wall of the protective shell, and then the protective shell is encased outside the mobile device. The heat absorption layer is thermally attached on the mobile device, the heat generated from the mobile device is transferred to the heat diffusion layer, and finally the heat is evenly transferred to the plastic base layer and the protective shell to perform heat dissipation. Therefore, the heat from the operating of the mobile device may be transferred from the heat dissipation film to the protective shell through the heat dissipation film for heat dissipation to make the protective shell possess desirable efficiency of heat dissipation.

### BRIEF DESCRIPTION OF THE DRAWINGS

FIG. 1 is a cross-sectional view of the heat dissipation film of the disclosure;

FIG. 2 is top view of the protective case for a mobile device of the disclosure;

FIG. 3 is a cross-sectional view of the protective case for a mobile device of the disclosure in use; and

FIG. 4 is a cross-sectional view of another embodiment of the heat dissipation film of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

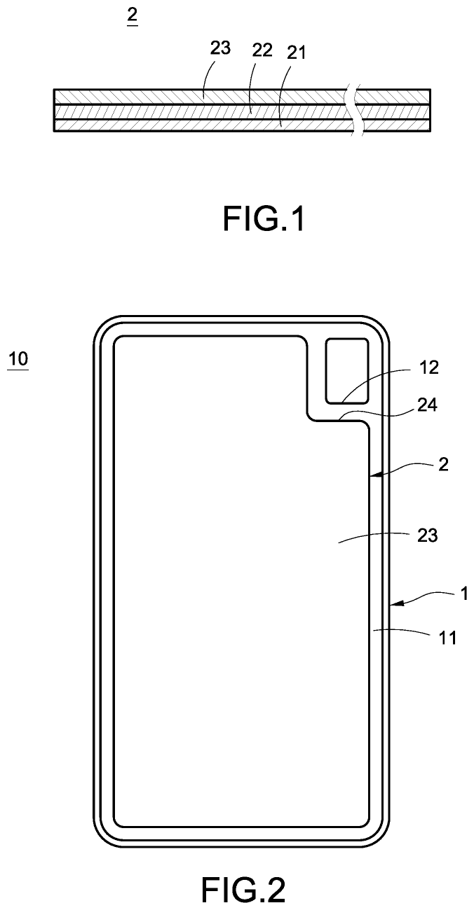

Please refer to FIGS. 1-3. The disclosure provides a protective case for a mobile device and a heat dissipation film thereof. The protective case 10 for the mobile device includes a protective shell 1 and a heat dissipation film 2. The heat dissipation film 2 includes a plastic base layer 21, a heat diffusion layer 22 and a heat absorption layer 23.

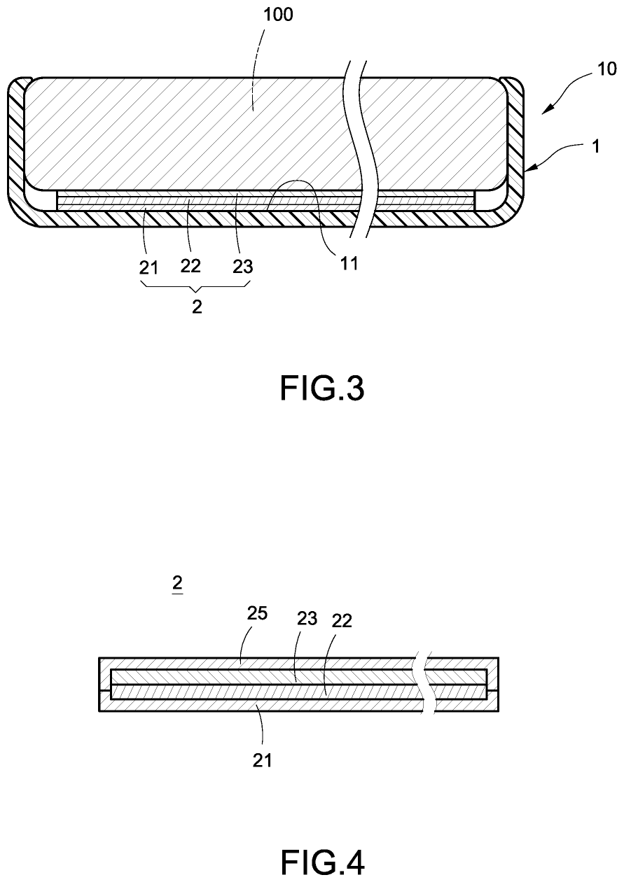

Please refer to FIGS. 2-3. The protective shell 1 is used to cover the surface of a mobile device 100 such as a tablet or a mobile phone to enhance the protective ability and the structural strength of the mobile device 100.

In addition, the inside of the protective shell 1 has an inner wall 11 and a lens hole 12 for exposing a lens (not shown) of the mobile device 100.

As shown in FIGS. 1-3, the heat dissipation film 2 is attached on the inner wall 11. The heat dissipation film 2 includes a plastic base layer 21, a heat diffusion layer 22 and a heat absorption layer 23 stacked sequentially in a direction away from the inner wall 11. That is, the heat diffusion layer 22 is sandwiched between the plastic base layer 21 and the heat absorption layer 23. The plastic base layer 11 is attached on the inner wall 11. The heat absorption layer 23 is attached on the mobile device 100.

The plastic base layer 21 is composed of polyethylene terephthalate (PET). The heat diffusion layer 22 is composed of a graphite sheet, a copper sheet, an aluminum sheet, a silver sheet or a graphene sheet. The heat absorption layer 23 is composed of a mix of a paraffin, a rubber and an endothermic powder. A thickness of the heat diffusion layer 22 is between 0.015 mm and 0.03 mm. A thickness of the heat absorption layer 23 is between 0.15 mm and 0.3 mm.

An outer periphery of the heat dissipation film 2 is concavely formed with a notch 24 corresponding to the lens hole 12 so that the lens (not shown) of the mobile phone 100 may not be blocked by the heat dissipation film 2.

In the embodiment, the heat diffusion layer 22 is attached on the plastic base layer 21 in a manner of adhesion, the heat absorption layer 22 is attached on the heat diffusion layer 22 in a manner of adhesion, and the plastic base layer 21 is attached on the inner wall 11 in a manner of adhesion. A side of the plastic base layer 21, which is opposite to (away from) the heat diffusion layer 22, may be coated with a pattern layer to increase aesthetic of the protective case 10.

Please refer to FIG. 3, which shows the use status of the protective case 10 and the heat dissipation film 2 of the disclosure. The heat dissipation film 2 is attached on the inner wall 11 of the protective shell 1, and then the protective shell 1 is encased outside the mobile device 100. The heat absorption layer 23 is thermally attached on the mobile device 100, the heat generated from the mobile device 100 is transferred to the heat diffusion layer 22, and finally the heat is evenly transferred to the plastic base layer 21 and the protective shell 1 to perform heat dissipation. Therefore, the heat from the operating of the mobile device 100 may be transferred from the heat dissipation film 2 to the protective shell 1 through the heat dissipation film 2 for heat dissipation to make the protective shell 1 possess desirable efficiency of heat dissipation.

Please refer to FIG. 4, which shows another embodiment of the heat dissipation film 2 of the disclosure. The embodiment of FIG. 4 is similar to the embodiment of FIGS. 1-3, the difference therebetween is that the heat diffusion layer 2 in FIG. 4 further includes an outer layer 25.

In detail, the outer layer 25 is attached on a side of the heat absorption layer 23, which is opposite to (away from) the heat diffusion layer 22. That is, the plastic base layer 21 and the outer layer 25 are jointly attached on two sides of the heat diffusion layer 22 and the heat absorption layer 23 opposite to each other, and the plastic base layer 21 and the outer layer 25 together fully cover external of the heat diffusion layer 22 and the heat absorption layer 23. The outer layer 25 is composed of polyethylene terephthalate or a fabric layer. Therefore, the same function and effect as the embodiment of FIGS. 1-3 may be accomplished.

In the embodiment, the heat diffusion layer 22 and the heat absorption layer 23 are attached with each other in a manner of adhesion, the plastic base layer 21 and the outer layer 25 are attached on two sides of the heat diffusion layer 22 and the heat absorption layer 23 opposite to each other in a manner of adhesion, and the plastic base layer 21 is attached on the inner wall 11 in a manner of adhesion. A side of the plastic base layer 21, which is opposite to (away from) the heat diffusion layer 22, may be coated with a pattern layer, and s side of the outer layer 25, which is exposed from the protective shell 1, may also be coated with a pattern layer to increase aesthetic of the protective case 10.

While this disclosure has been described by means of specific embodiments, numerous modifications and variations could be made thereto by those skilled in the art without departing from the scope and spirit of this disclosure set forth in the claims.

What is claimed is:

1. A heat dissipation film, comprising:
a plastic base layer, composed of polyethylene terephthalate (PET);
a heat diffusion layer, composed of a graphite sheet, a copper sheet, an aluminum sheet, a silver sheet or a graphene sheet; and
a heat absorption layer, composed of a mix of a paraffin, a rubber and an endothermic powder, and the heat diffusion layer being sandwiched between the plastic base layer and the heat absorption layer.

2. The heat dissipation film of claim 1, wherein a thickness of the heat diffusion layer is between 0.015 mm and 0.03 mm, and a thickness of the heat absorption layer is between 0.15 mm and 0.3 mm.

3. The heat dissipation film of claim 1, further comprising: an outer layer, attached on a side of the heat absorption layer away from the heat diffusion layer, wherein the plastic base layer and the outer layer together fully cover external of the heat diffusion layer and the heat absorption layer, and the outer layer is composed of polyethylene terephthalate or a fabric layer.

4. The heat dissipation film of claim 1, wherein a notch is disposed concavely on an outer periphery of the heat dissipation film.

5. A protective case for a mobile device, the protective case comprising:
a protective shell, comprising an inner wall; and
a heat dissipation film, attached on the inner wall, and comprising a plastic base layer, a heat diffusion layer and a heat absorption layer stacked sequentially in a direction away from the inner wall.

6. The protective case of claim 5, wherein the plastic base layer is composed of polyethylene terephthalate.

7. The protective case of claim 5, wherein the heat diffusion layer is composed of a graphite sheet, a copper sheet, an aluminum sheet, a silver sheet or a graphene sheet, and a thickness of the heat diffusion layer is between 0.015 mm and 0.03 mm.

8. The protective case of claim 5, wherein the heat absorption layer is composed of a mix of a paraffin, a rubber and an endothermic powder, and a thickness of the heat absorption layer is between 0.15 mm and 0.3 mm.

9. The protective case of claim 5, wherein the heat dissipation film further comprises an outer layer attached on a side of the heat absorption layer away from the heat diffusion layer, wherein the plastic base layer and the outer layer together fully cover external of the heat diffusion layer and the heat absorption layer, and the outer layer is composed of polyethylene terephthalate or a fabric layer.

10. The protective case of claim 5, wherein a lens hole is disposed on the protective shell, and a notch is disposed concavely on an outer periphery of the heat dissipation film corresponding to the lens hole.
